(19) United States
(12) Patent Application Publication
(10) Pub. No.: US 2019/0170814 A1
(43) Pub. Date: Jun. 6, 2019

(54) BURN-IN TEST DEVICE AND TEST METHOD USING INTERPOSER

(71) Applicant: Samsung Electronics Co., Ltd., Suwon-si (KR)

(72) Inventor: Joosung YUN, Asan-si (KR)

(21) Appl. No.: 16/013,382

(22) Filed: Jun. 20, 2018

(30) Foreign Application Priority Data
Dec. 5, 2017 (KR) 10-2017-0166221

(51) Int. Cl. G01R 31/28; G11C 29/06; G11C 29/56

(52) U.S. Cl. CPC G01R 31/2884; G01R 31/2862; G01R 31/2863; G11C 29/56012; G11C 29/06; G11C 29/56004; G01R 31/2882

(57) ABSTRACT

A test device includes a connecting circuit and a chamber. The connecting circuit includes an interposer to transfer a test signal to operate a device under test. The chamber includes a pin electronic circuit to generate a control signal to control an operation of the device under test based on the test signal received through the interposer. The pin electronic circuit is spatially disposed within the chamber and generates the control signal. When the test signal is received, an internal temperature of the chamber is higher or lower than an external temperature of the chamber when the test signal is received.

### CROSS-REFERENCE TO RELATED APPLICATIONS

Korean Patent Application No. 10-2017-0166221 filed on Dec. 5, 2017, and entitled, “Burn-In Test Device and Test Method Using Interposer,” is incorporated by reference herein in its entirety.

### BACKGROUND

### 1. Field

One or more embodiments described herein relate to a burn-in test device and a test method using an interposer.

### 2. Description of the Related Art

A semiconductor device may be manufactured at a wafer level and assembled into a semiconductor package. The assembled package is finally tested before it is provided to a user. The test may involve removing defective products and selecting only good products. Such a test may reduce semiconductor failure rate.

One test, known as a burn-in test, is associated with the lifespan and reliability of a semiconductor device. In a burn-in test, a semiconductor device operates in a high-temperature environment for a given time. The burn-in test allows the semiconductor memory device to experience considerable stress in a short time in an environment more severe than an environment where the semiconductor device is expected to actually be used. In this case, it may be possible to identify memory cells capable of causing operation failure before shipment.

The burn-in test may be performed by handler and chamber structures. The distance between a connector of the chamber structure and a device under test (DUT) is longer than the distance between a connector of the handler structure and the DUT. As the distance between the connector and the DUT becomes relatively long in the chamber structure, signals transferred to the DUT in the chamber structure may be distorted.

### SUMMARY

In accordance with one or more embodiments, a test device includes a connecting circuit including an interposer to transfer a test signal to operate a device under test; and a chamber including a pin electronic circuit to generate a control signal to control an operation of the device under test based on the test signal from the interposer, wherein the pin electronic circuit is spatially disposed within the chamber and generates the control signal, and wherein an internal temperature of the chamber is higher or lower than an external temperature of the chamber when the test signal is received.

In accordance with one or more other embodiments, a test device includes a system circuit to generate a test signal to test an operation of a device under test based on a request of a host; a chamber including a pin electronic circuit to generate a control signal to control the operation of the device under test based on the test signal; and a connector to electrically connect the system circuit and the chamber by an interposer stacked between the system circuit and the chamber, wherein an internal temperature of the chamber is higher or lower than an external temperature of the chamber based on the request of the host to test the operation of the device under test.

In accordance with one or more other embodiments, a test method performed by a test device to test a device under test includes generating, by a system circuit of the test device, a test signal to test the device under test; transferring the test signal through an interposer stacked between the system circuit and the test device; generating, by a pin electronic circuit spatially disposed within the chamber, a control signal to control an operation of the device under test based on the test signal transferred through the interposer; and testing the device under test based on the control signal at a temperature that is higher or lower than an external temperature of the chamber.

In accordance with one or more other embodiments, a non-transitory, computer-readable medium comprising instructions which, when executed, cause a processor to perform a method of generating, by a system circuit of the test device, a test signal to test the device under test; transferring the test signal through an interposer stacked between the system circuit and the test device; generating, by a pin electronic circuit spatially disposed within the chamber, a control signal to control an operation of the device under test based on the test signal transferred through the interposer; and testing the device under test based on the control signal at a temperature that is higher or lower than an external temperature of the chamber.

### BRIEF DESCRIPTION OF THE FIGURES

Features will become apparent to those of skill in the art by describing in detail exemplary embodiments with reference to the attached drawings in which:

FIG. 1 illustrates an embodiment of a test device and a host;

FIG. 2 illustrates another embodiment of a test device;

FIG. 3 illustrates an embodiment of a host and a system circuit;

FIG. 4 illustrates an embodiment of a host and a site board;

FIG. 5 illustrates an embodiment of a connecting unit;

FIG. 6 illustrates an embodiment of a chamber;

FIG. 7 illustrates an embodiment of a burn-in board;

FIGS. 8A and 8B illustrate embodiments of configurations and operations associated with a test device;

FIG. 9 illustrates an embodiment of a connector;

FIG. 10 illustrates an embodiment of an interposer; and

FIG. 11 illustrates an embodiment of the operation of a test device.

### DETAILED DESCRIPTION

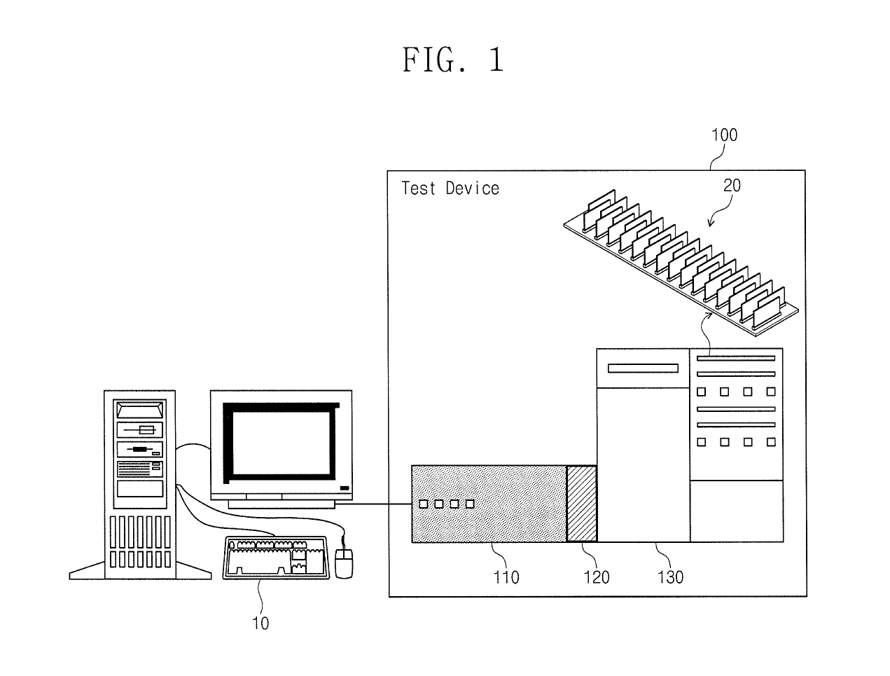

FIG. 1 illustrates an embodiment of a host 10 and a test device 100, the latter of which may include a system circuit 110, a connecting unit 120, and a chamber 130. The chamber 130 may include a device under test (DUT) 20. The DUT 20 may correspond to device to be tested by the test device 100. The DUT 20 may be mounted in and tested by the test device 100, and then may be separated from the test device 100. The DUT 20 may be, for example, a semiconductor device. In one embodiment, the DUT 20 may be a large scale integration (LSI) device or another type of semiconductor device.

The host 10 may include a terminal or other device which allows a user to input a command for testing the DUT 20. For example, the host 10 may transfer a request for testing the DUT 20 to the system circuit 110 based on the user command. The system circuit 110 may be connected with the chamber 130 through the connecting unit 120. As an example, the system circuit 110 may be electrically connected with the DUT 20 in the chamber 130 by the connecting unit 120.

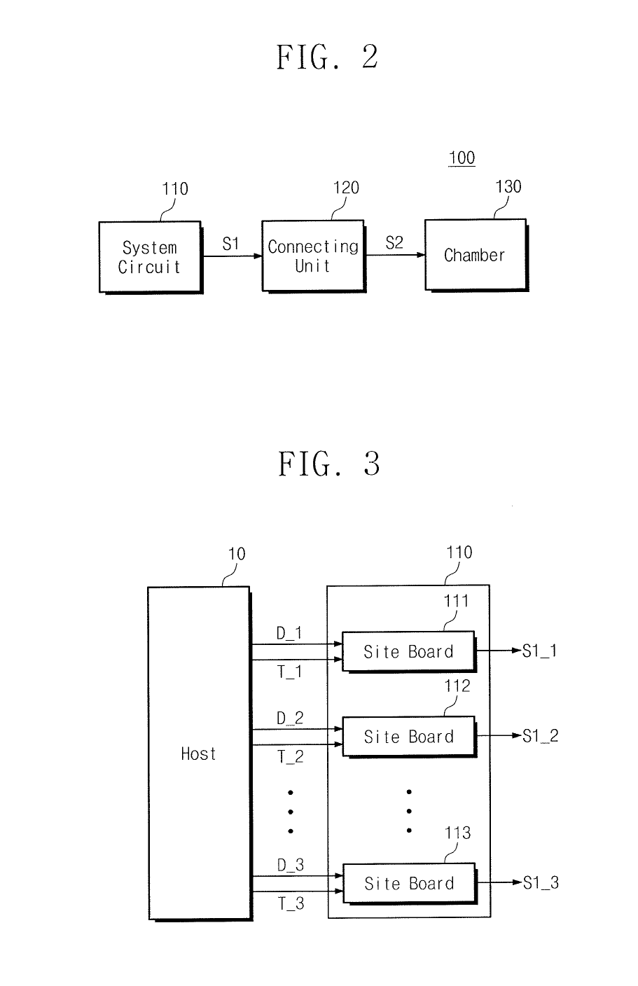

FIG. 2 illustrates an embodiment of a test device, which, for example, may correspond to the test device 100 of FIG. 1. Referring to FIG. 2, the system circuit 110 may receive signals indicating a request of the host 10 of FIG. 1. To test the DUT 20, the system circuit 110 may generate a test signal S1 for operating the DUT 20 based on the signals from the host 10 of FIG. 1.

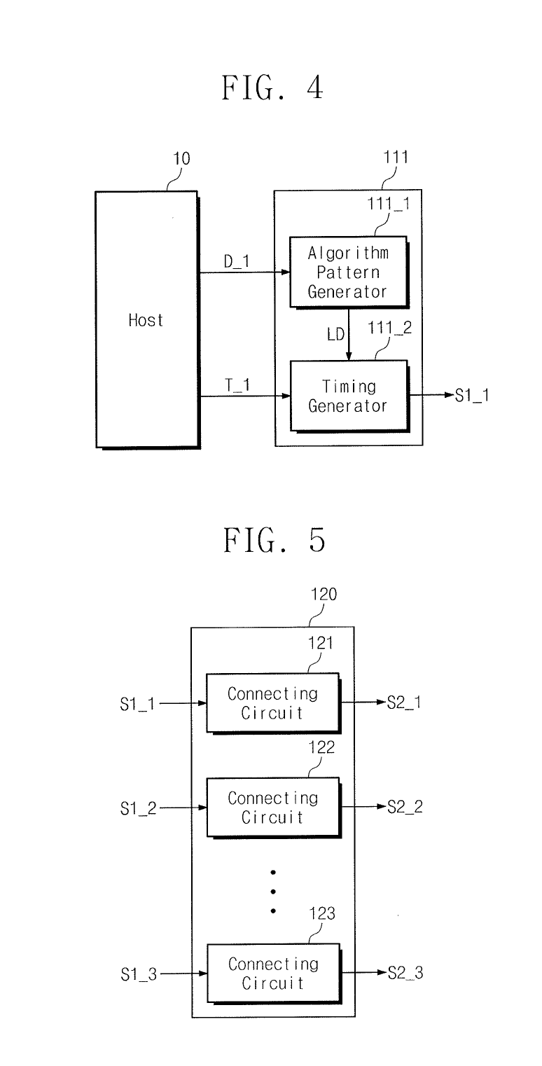

As an example, the test signal S1 may be associated with a burn-in test. The burn-in test may corresponds to a process for testing whether a device under test operates normally in an environment where a temperature is greater than a specific temperature or is lower than a specific temperature. As an example, the test device 100 may be a burn-in test device. The test signal S1 may indicate data having logical values. The system circuit 110 may output the test signal S1 to the connecting unit 120. Example embodiments of the system circuit 110 and the test signal S1 are described with reference to FIGS. 3 and 4.

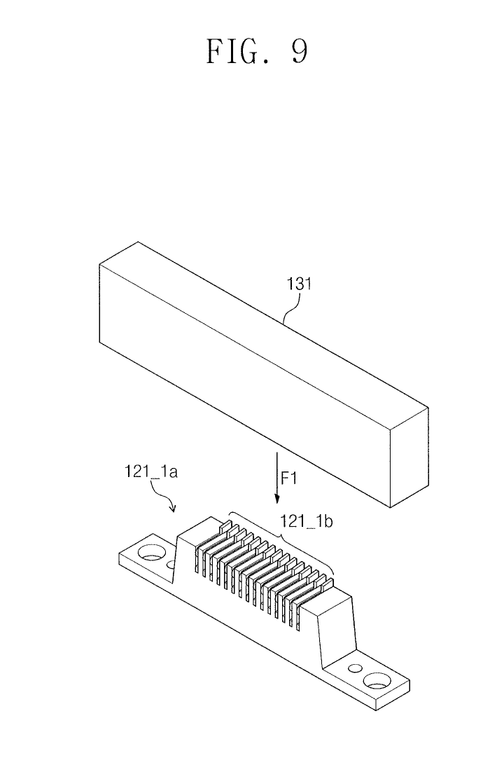

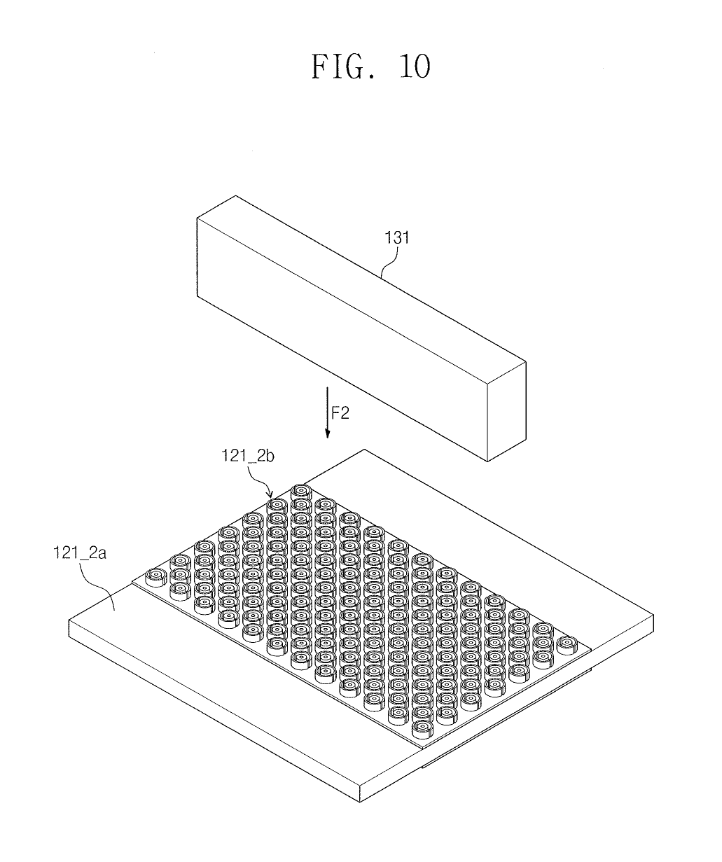

The connecting unit 120 may connect the system circuit 110 and the chamber 130. As an example, the connecting unit 120 may electrically connect the system circuit 110 and the chamber 130. The connecting unit 120 may include one or more conductors for passing a signal received from the system circuit 110 to the chamber 130. As an example, the connecting unit 120 may include at least one conductor such as a connector or an interposer. Example embodiments of a connector and an interposer are described with reference to FIGS. 9 and 10, respectively.

The connecting unit 120 may receive the test signal S1 from the system circuit 110. The connecting unit 120 may pass the received test signal S1 and output a test signal S2. The test signal S2 may correspond to the test signal S1. As an example, data indicated by the test signal S2 may be identical to data indicated by the test signal S1. The connecting unit 120 may output the test signal S2 to the chamber 130.

Each of the test signals S1 and S2 is illustrated in FIG. 2 as one signal. In one embodiment, the system circuit 110 may generate and output one or more test signals and the connecting unit 120 may pass the one or more test signals (e.g., refer to FIGS. 3 and 5).

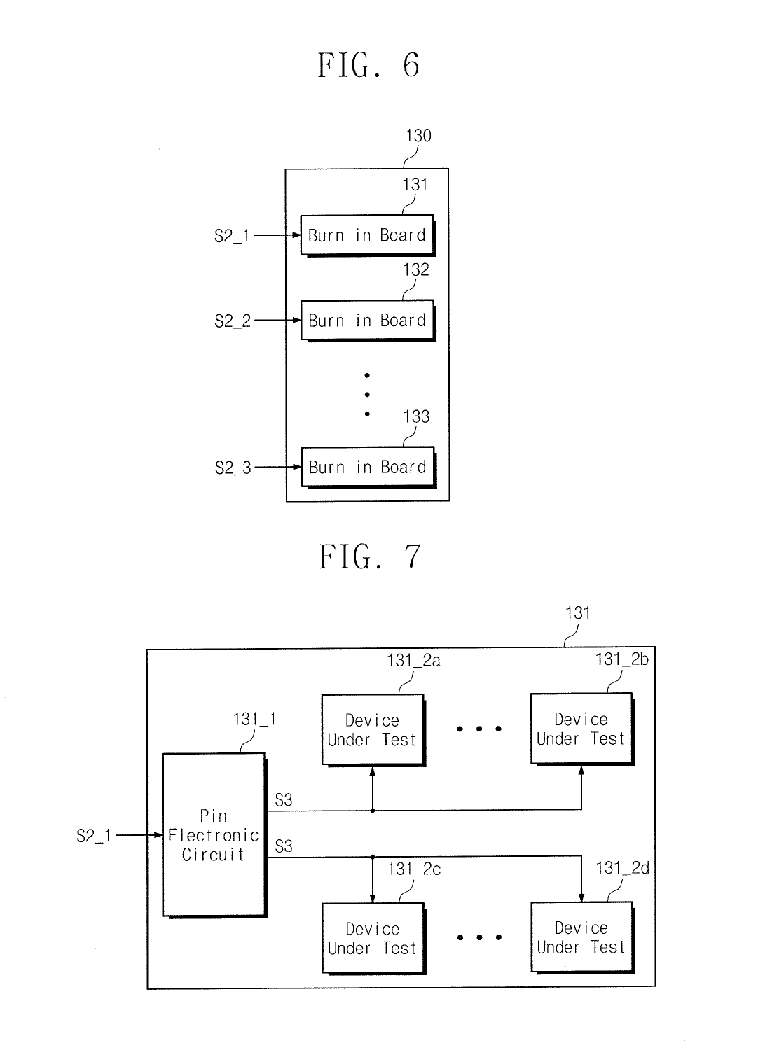

The chamber 130 may receive the test signal S2 from the connecting unit 120. The chamber 130 may include devices under test. As an example, the chamber 130 may include the DUT 20 of FIG. 1. As an example, for the burn-in test, an internal temperature of the chamber 130 may be higher than an external temperature of the chamber 130 by a first reference temperature or higher. As an example, the internal temperature of the chamber 130 may be not lower than 125° C. In one embodiment, for the test, an internal temperature of the chamber 130 may be lower than an external temperature of the chamber 130 by a second reference temperature or lower. As an example, the internal temperature of the chamber 130 may be not higher than −20° C. An example embodiment of the chamber 130 is described with reference to FIG. 6.

FIG. 3 illustrating another embodiment of a host and a system circuit, which, for example, may correspond to FIGS. 1 and 2. As described with reference to FIG. 1, the host 10 may be outside the test device 100 of FIG. 2. As an example, the host 10 may include a processor to generate a signal for performing a test operation. For example, the host 10 may be a general-purpose processor, a workstation processor, an application processor, and or another type of processing or computing device. The host 10 may include a single processor core or a plurality of processor cores (a multi-core). For example, the host 10 may include a multi-core such as a dual-core, a quad-core, or a hexa-core.

The system circuit 110 may include site boards 111 to 113. FIG. 3 shows the system circuit 110 including three or more site boards 111 to 113. In one embodiment, the system circuit 110 may include one or more site boards. The site boards 111 to 113 may receive data signals D_1 to D_3 and timing signals T_1 to T_3 from the host 10, respectively. The site boards 111 to 113 may generate test signals S1_1 to S1_3, respectively. The site boards 111 to 113 may output the test signals S1_1 to S1_3, respectively. An example of the operation of the site board 111 is described below. The site boards 112 and 113 may operate similar to operation of the site board 111.

The site board 111 may receive the data signal D_1 and the timing signal T_1 from the host 10. The site board 111 may generate the test signal S1_1 based on the data signal D_1 and the timing signal T_1. The test signal S1_1 may include logical values associated with data indicated by the data signal D_1.

The data signal D_1 and the timing signal T_1 may be associated with an operation of testing a device under test. The data signal D_1 may control an operation of testing a device under test. As an example, when a device under test is a memory device, the data signal D_1 may indicate data for controlling one or more read and write operations. The timing signal T_1 may indicate data associated with timing. As an example, the timing signal T_1 may indicate data associated with a time interval where a logical value of the test signal S1_1 is maintained.

The test signal S1_1 may indicate data for testing devices under test. The site board 111 may output the test signal S1_1 to the connecting unit 120. The test signal S1_1 may be associated with operations for testing a device under test. An example of the test signal S1_1 is described with reference to FIG. 4.

FIG. 4 illustrates an embodiment of a site board 111 of FIG. 3 and a host.

Referring to FIG. 4, the site board 111 may include an algorithm pattern generator (ALPG) 111_1 and a timing generator (TG) 111_2. The algorithm pattern generator 111_1 may generate logic data for performing a test operation based on the data signal D_1 from the host 10. The algorithm pattern generator 111_1 may generate a logic data signal LD indicating logic data. The algorithm pattern generator 111_1 may output the logic data signal LD to the timing generator 111_2.

As an example, when a device under test is a memory device, the data signal D_1 may indicate data for controlling a write command. As an example, the logic data may be associated with data to be stored in a device under test or an address corresponding to a specific location in the device under test. The logic data may indicate a logical value for controlling an operation of the device under test. The logic data may include data where logical values of “1” and logical values of “0” are arranged in a specific pattern.

The timing generator 111_2 may receive the logic data signal LD from the algorithm pattern generator 111_1. The timing generator 111_2 may receive the timing signal T_1 from the host 10. The timing generator 111_2 may generate the test signal S1_1 having a logical value of the logic data signal LD during a specific time interval based on the logic data signal LD and the timing signal T_1. The timing generator 111_2 may adjust the specific time interval, based on the timing signal T_1.

As an example, the timing generator 111_2 may adjust a time point when a logical value of the test signal S1_1 changes. As an example, by the timing generator 111_2, the logical value of the test signal S1_1 may be maintained at the logical value “1” during a first time interval and may be then changed to the logical value “0”. The logical value of the test signal S1_1 may be maintained at the logical value “0” during a second time interval. The lengths of the first time interval and the second time interval may be adjusted by the timing generator 111_2. The timing generator 111_2 may output the test signal S1_1 to the connecting unit 120 of FIG. 2.

Since the test signal S1_1 is generated based on the data signal D_1 and the timing signal T_1, the test signal S1_1 may be associated with an operation for perform a test operation. As an example, when a device under test is a memory device, the test signal S1_1 may indicate data for controlling a write operation. As an example, the test signal S1_1 may indicate data for controlling the write operation of the memory device, data indicating an address of the memory device, and data to be stored at a location corresponding to the address.

The system circuit 110 may be implemented with at least one of an application specific integrated circuit (ASIC) and a field programmable gate array (FPGA). As an example, the algorithm pattern generator 111_1 and the timing generator 111_2 may be implemented with at least one of the ASIC and the FPGA.

FIG. 5 illustrates an embodiment of the connecting unit 120 of FIG. 2. Referring to FIG. 5, the connecting unit 120 may include connecting circuits 121 to 123. In one embodiment, the connecting unit 120 may include a different number of connecting units, e.g., one or more connecting circuits.

The connecting circuits 121 to 123 may receive the test signals S1_1 to S1_3 from the site boards 111 to 113, respectively. The connecting circuits 121 to 123 may pass the test signals S1_1 to S1_3 to output test signals S2_1 to S2_3, respectively. Accordingly, the test signals S2_1 to S2_3 may correspond to the test signals S1_1 to S1_3, respectively. As an example, data indicated by the test signals S2_1 to S2_3 may be substantially identical to data indicated by the test signals S1_1 to S1_3.

Each of the connecting circuits 121 to 123 may include a conductor or device for passing a current, e.g., an interposer or a connector. Each of the connecting circuits 121 to 123 may electrically connect the system circuit 110 and the chamber 130. The connecting circuits 121 to 123 may electrically connect the site boards 111 to 113 of FIG. 3 and burn-in boards, such as described, for example, with reference to FIG. 6

FIG. 6 illustrates an embodiment of the chamber 130 of FIG. 2 which may include burn-in boards 131 to 133. The burn-in boards 131 to 133 may receive the test signals S2_1 to S2_3, respectively. FIG. 6 shows that the chamber 130 includes three or more burn-in boards 131 to 133. In one embodiment, the chamber 130 may include a different number of burn-in boards, e.g., one or more burn-in boards. An example of the configuration and operation of the burn-in board 131 is described below. Configurations and operations of the burn-in boards 132 and 133 may be similar to the operation of the burn-in board 131.

One or more devices under test may be mounted in the burn-in board 131. As an example, the burn-in board 131 may include sockets into which devices under test are inserted. The devices under test may be respectively inserted into the sockets. The burn-in board 131 may include a pin electronic (PE) circuit to generate a control signal for a test operation (e.g., refer to FIG. 7). The devices under test may be tested by the control signal generated based on the test signal S2_1.

As described with reference to FIG. 2, an internal temperature of the chamber 130 may be higher or lower than an external temperature of the chamber 130. Accordingly, the devices under test may be tested in a high-temperature or low-temperature condition.

FIG. 7 illustrates an embodiment of the burn-in board of FIG. 6. Referring to FIG. 7, the burn-in board 131 may include a pin electronic circuit 131_1 and devices under test 131_2a to 1312d. FIG. 7 shows that the burn-in board 131 includes four or more devices under test 131_2a to 131_2d. In one embodiment, the burn-in board 131 may include one or more devices under test.

The pin electronic circuit 131_1 may receive the test signal S2_1 from the connecting circuit 121. The pin electronic circuit 131_1 may generate a control signal S3 for controlling operations of the devices under test 131_2a to 131_2d based on the test signal S2_1. The pin electronic circuit 131_1 may be spatially arranged within the chamber 130 and may output the control signal S3 to the devices under test 131_2a to 131_2d.

Each of the devices under test 131_2a to 131_2d may receive the control signal S3 from the pin electronic circuit 131_1. Each of the devices under test 131_2a to 131_2d may operate based on the control signal S3. As an example, each of the devices under test 131_2a to 131_2d may include a memory device. Each of the devices under test 131_2a to 131_2d may perform write and read operations based on the control signal S3. As described with reference to FIG. 2, the devices under test 131_2a to 131_2d may be tested in a high-temperature or low-temperature condition.

The pin electronic circuit 131_1 may be implemented with at least one of the ASIC and the FPGA. As an example, the pin electronic circuit 131_1 may be implemented with at least one of the ASIC and the FPGA that operate at a high temperature (e.g., a temperature of 125° C. or higher) and a low temperature (e.g., a temperature of −20° C. or lower).

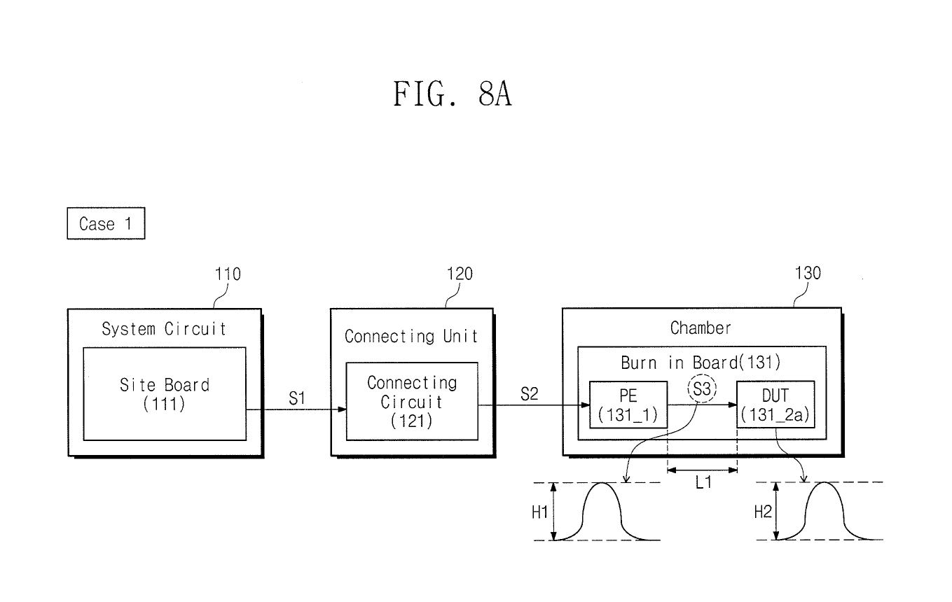

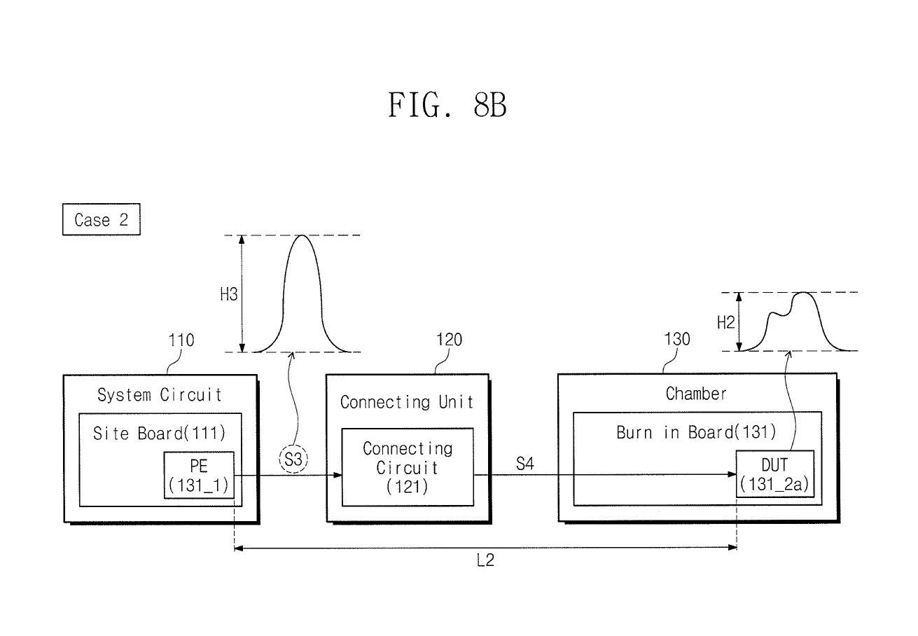

FIGS. 8A and 8B illustrate exemplary embodiments of configurations and operations associated with a test device. In a first case of FIG. 8A, the pin electronic circuit 131_1 may be within the burn-in board 131. The configuration and operation of the test device 100 of FIG. 8A may be similar to those described with reference to FIGS. 1 to 7.

In a second case of FIG. 8B, the pin electronic circuit 131_1 may be outside the burn-in board 131. As an example, the pin electronic circuit 131_1 may be within the site board 111. When the pin electronic circuit 131_1 is within the site board 111, the control signal S3 may be transferred through the connecting circuit 121. The connecting circuit 121 may pass the control signal S3 to output a control signal S4 to a device under test. The control signal S4 may correspond to the control signal S3. As an example, data indicated by the control signal S3 may be substantially identical to data indicated by the control signal S4.

Referring to the first case of FIG. 8A, since the control signal S3 is generated within the chamber 130, the control signal S3 may be directly transferred to a device under test 131_2a from the pin electronic circuit 131_1. During the signal transfer process, the magnitude of the control signal S3 may decrease. Accordingly, the magnitude “H2” of the control signal S3 received by the device under test 131_2a may be less than the magnitude “H1” of the control signal S3 output from the pin electronic circuit 131_1.

Referring to the second case of FIG. 8B, since the control signal S4 is generated outside the chamber 130, the control signal S3 may be transferred to the device under test 131_2a from the pin electronic circuit 131_1 through the connecting circuit 121. The magnitude of the control signal S3 may decrease by the connecting circuit 121 in the process where the control signal S3 is transferred through the connecting circuit 121. Accordingly, the magnitude “H2” of the control signal S4 received by the device under test 131_2a may be less than the magnitude “H3” of the control signal S3.

Referring to FIGS. 8A and 8B together, for transferring the control signal S3 or S4 having the magnitude of “H2” to the device under test 131_2a, the magnitude of the control signal S3 output from the pin electronic circuit 131_1 may be “H1” in the first case and may be “H3” in the second case. “H3” may be greater than “H1”. For transferring the control signal S4 having a uniform magnitude to the device under test 131_2a, the pin electronic circuit 131_1 of the second case may output the control signal S3, the magnitude of which is greater than the magnitude of the control signal S4 of the first case. Accordingly, the pin electronic circuit 131_1 of the second case may consume more power than the pin electronic circuit 131_1 of the first case.

A path between the pin electronic circuit 131_1 and the device under test 131_2a may be implemented with a wire (or a conducting line) or the like. As the wire becomes longer, inductance of the wire may increase. Accordingly, as the wire becomes longer, a signal transferred through the wire may be distorted by the inductance of the wire to a greater extent.

In the first case of FIG. 8A, the distance from the pin electronic circuit 131_1 to the device under test 131_2a may be L1. In the second case of FIG. 8B, the distance from the pin electronic circuit 131_1 to the device under test 131_2a may be L2. In one embodiment, L2 may be greater than L1. For example, the distance from the pin electronic circuit 131_1 to the device under test 131_2a in the second case may be longer than the distance from the pin electronic circuit 131_1 to the device under test 131_2a in the first case. A wire for implementing a path from the pin electronic circuit 131_1 to the device under test 131_2a in the first case may be longer than a wire for implementing a path from the pin electronic circuit 131_1 to the device under test 131_2a in the second case.

Accordingly, the control signal S3 received by the device under test 131_2a in the first case may be distorted to be less than the control signal S4 received by the device under test 131_2a in the second case. This may mean that the control signal S3 of the first case indicates more accurate data than the control signal S4 of the second case.

As described above, the inductance of the wire having a length corresponding to L1 in the first case may be less than the inductance of the wire having a length corresponding to L2 in the second case. As the frequency of a signal transferred through a wire becomes higher, the transferred signal may be distorted by the inductance of the wire to a greater extent.

In addition, as the inductance of the wire becomes greater, a high-frequency signal transferred through the wire may be distorted to a greater extent. Accordingly, when the control signal S3 includes a high-frequency signal, the device under test 131_2a of the first case may receive a less distorted signal from the pin electronic circuit 131_1 than the device under test 131_2a of the second case.

As the frequency of a signal transferred through a wire becomes higher, the transferred signal may be greatly distorted when passing through the connecting circuit 121. As an example, the transferred signal may be distorted by crosstalk Xtalk. As an example, the distorted signal may include a skew. In the first case, since the control signal S3 is transferred to the device under test 131_2a after being generated within the chamber 130, the control signal S3 may not pass through the connecting circuit 121. Accordingly, the control signal S3 received by the device under test 131_2a in the first case may be distorted to be less than the control signal S4 received by the device under test 131_2a in the second case.

The second case of FIG. 8B illustrates the pin electronic circuit 131_1 within the site board 111. However, in one embodiment, the second case may be associated with examples of the device under test 131_2a outside the burn-in board 131.

FIG. 9 illustrates an embodiment of a connector that may be included in in the connecting circuit of FIG. 5. Referring to FIG. 9, the burn-in board 131 may be coupled with a connector 121_1a. The connector 121_1a may include a coupling part 121_1b to be coupled with the burn-in board 131. The coupling part 121_1b may include a conductive material for electrically connecting the system circuit 110 and the chamber 130 of FIG. 2. The connector 121_1a may transfer the test signal S1 from the system circuit 110 to the chamber 130 through the coupling part 121_1b. The burn-in board 131 may include pins for receiving a signal from the connector 121_1a.

A contact force “F1” may be required to couple the burn-in board 131 with the coupling part 121_1b. As the number of pins in the burn-in board 131 increases, a contact force for coupling the burn-in board 131 with the coupling part 121_1b may increase. The connector 121_1a may be worn out when the burn-in board 131 is coupled with the coupling part 121_1b. The connector 121_1a may be worn out more quickly as the contact force becomes greater.

As an example, the burn-in board 131 may include a power pin to receive power for operating a device under test. The power pin may receive more electrical energy than any of the other pins. For this reason the thickness of the power pin may be greater than those of the other pins. Accordingly, the connector 121_1a may be worn out when the burn-in board 131 is coupled with the coupling part 121_1b.

FIG. 10 illustrates an embodiment of an interposer that may be included in the connecting circuit of FIG. 5. Referring to FIG. 10, the burn-in board 131 may be coupled with an interposer 121_2a that may include one or more coupling parts. As an example, the interposer 121_2a may include a coupling part 121_2b that may electrically connect the system circuit 110 and the chamber 130 of FIG. 2. As an example, the interposer 121_2a may be stacked between the system circuit 110 and the chamber 130. The interposer 121_2a may include a conductive material for connecting the system circuit 110 and the chamber 130. Referring to FIG. 2, the interposer 121_2a may transfer the test signal S1 from the system circuit 110 to the chamber 130 through the coupling part 121_2b.

The burn-in board 131 may include pins for receiving a signal from the interposer 121_2a. A contact force “F2” may be required to couple the burn-in board 131 with coupling parts of the interposer 121_2a. As the number of pins in the burn-in board 131 increases, a contact force for coupling the burn-in board 131 with the coupling parts of the interposer 121_2a may increase. The interposer 121_2a may be worn out when the burn-in board 131 is coupled with the coupling parts of the interposer 121_2a.

Referring to FIGS. 9 and 10 together, the contact force “F1” may be greater than the contact force “F2”. Accordingly, the interposer 121_2a may wear out more slowly than the connector 121_1a. Thus, the durability of the connecting circuit 121 including the interposer 121_2b may be higher than the durability of the connecting circuit 121 including the connector 121_1a. Accordingly, when the connecting circuit 121 is to be implemented with a specific durability, the burn-in board 131 coupled with the interposer 121_2b may include more pins than the burn-in board 131 coupled with the connector 121_1a.

As the burn-in board includes more pins, more pins may be assigned to ground pins. As the number of ground pins in the burn-in board 131 increases, distortion of a signal transferred to the burn-in board 131 through the connecting circuit 121 may decrease. Accordingly, the signal transferred through the interposer 121_2b may be distorted to a lesser extent than the signal transferred through the connector 121_1a. In addition, since the contact force “F1” is greater than the contact force “F2”, the interposer 121_2a may be more easily replaced than the connector 121_1a.

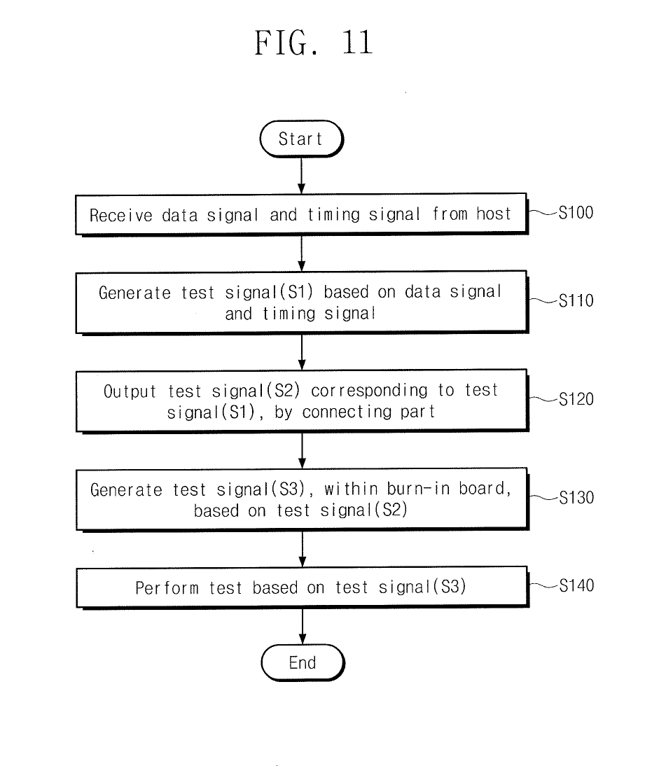

FIG. 11 illustrates an embodiment of the operation of the test device of FIG. 2. In operation S100, the system circuit 110 may receive a data signal and a timing signal from the host 10. As an example, the host 10 may be a processor outside the test device 100. As an example, the data signal may be associated with an operation of a device under test. As an example, the timing signal may be associated with timing.

In operation S110, the system circuit 110 may generate the test signal S1 based on the data signal and the timing signal. The system circuit 110 may include one or more site boards. site board may include an algorithm pattern generator and a timing generator.

The algorithm pattern generator may generate a logic data signal indicating logic data based on the data signal. The timing generator may generate the test signal S1 based on the logic data signal and the timing signal. As an example, the timing generator may generate the test signal S1 having a logical value of the logic data during a time interval determined based on the timing signal.

In operation S120, the connecting unit 120 may receive the test signal. The connecting unit 120 may include one or more connecting circuits. The connecting unit may pass the test signal S1 to output the test signal S2 to the chamber 130. As an example, the connecting circuit may include an interposer.

In operation S130, the chamber 130 may receive the test signal S2 from the connecting unit 120. The chamber 130 may include one or more burn-in boards. One or more devices under test and a pin electronic circuit may be mounted in the burn-in board. The pin electronic circuit may generate the control signal S3 for controlling operations of the devices under test based on the test signal S2. As an example, the pin electronic circuit may be implemented with at least one of the ASIC and the FPGA.

In operation S140, the devices under test may receive the control signal S3. The devices under test may be tested by the control signal S3. As described with reference to FIG. 2, an internal temperature of the chamber 130 may be higher or lower than an external temperature of the chamber 130. Accordingly, the devices under test may be tested in a high-temperature or low-temperature environment. As an example, when a device under test is a memory device, the device under test may perform read and write operations.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods herein.

The processors, controllers, algorithm pattern generators, timing generators, and other signal providing, signal generating, and signal processing features of the embodiments described herein may be implemented in non-transitory logic which, for example, may include hardware, software, or both. When implemented at least partially in hardware, the processors, controllers, algorithm pattern generators, timing generators, and other signal providing, signal generating, and signal processing features may be, for example, an integrated circuit including but not limited to an application-specific integrated circuit, a field-programmable gate array, a combination of logic gates, a system-on-chip, a microprocessor, or another type of processing or control circuit.

When implemented in at least partially in software, the processors, controllers, algorithm pattern generators, timing generators, and other signal providing, signal generating, and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods herein.

The various operations of methods described above may be performed by any suitable means capable of performing the operations, such as various hardware and/or software component(s), circuits, and/or module(s).

The software may comprise an ordered listing of executable instructions for implementing logical functions, and can be embodied in any “processor-readable medium” for use by or in connection with an instruction execution system, apparatus, or device, such as a single or multiple-core processor or processor-containing system.

The blocks or operations of a method or algorithm and functions described in connection with the embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

In accordance with one or more of the aforementioned embodiments, distortion of a signal transferred to a device under test may decrease in the test process. Also, durability of a test device may be improved.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise indicated. Accordingly, various changes in form and details may be made without departing from the spirit and scope of the embodiments set forth in the claims.

1. A test device, comprising:
a connecting circuit including an interposer to transfer a test signal to operate a device under test; and
a chamber including a pin electronic circuit to generate a control signal to control an operation of the device under test based on the test signal received through the interposer, wherein the pin electronic circuit is spatially disposed within the chamber and generates the control signal, and wherein an internal temperature of the chamber is higher or lower than an external temperature of the chamber when the test signal is received.

2. The test device as claimed in claim 1, wherein the pin electronic circuit is implemented with at least one of an application specific integrated circuit (ASIC) and a field programmable gate array (FPGA).

3. The test device as claimed in claim 1, further comprising:
a system circuit to generate the test signal based on a data signal and a timing signal from a host.

4. The test device as claimed in claim 3, wherein the interposer is stacked between the system circuit and the chamber.

5. The test device as claimed in claim 3, wherein:
the data signal corresponds to control of the operation of the device under test, and
the timing signal corresponds to a time interval where a logical value of the test signal is maintained.

6. The test device as claimed in claim 3, wherein the system circuit includes:
an algorithm pattern generator to generate logic data to test the operation of the device under test based on the data signal.

7. The test device as claimed in claim 6, wherein the system circuit further includes a timing generator to:
adjust a time interval, in which the test signal is maintained with a logical value of the logic data, based on the timing signal, and
output the test signal.

8. The test device as claimed in claim 1, wherein:
the device under test includes a memory device to store data, and
the test signal corresponds to control of the memory device, an address of the memory device, and data to be stored at a location corresponding to the address.

9. A test device, comprising:
a system circuit to generate a test signal to test an operation of a device under test based on a request of a host;
a chamber including a pin electronic circuit to generate a control signal to control the operation of the device under test based on the test signal; and
a connector to electrically connect the system circuit and the chamber by an interposer stacked between the system circuit and the chamber, wherein an internal temperature of the chamber is higher or lower than an external temperature of the chamber based on the request of the host to test the operation of the device under test.

10. The test device as claimed in claim 9, wherein:
the device under test includes a memory device, and
the test signal is to control read and write operations of the memory device.

11. The test device as claimed in claim 9, wherein the chamber includes:
a burn-in board to mount the device under test.

12. The test device as claimed in claim 9, wherein the interposer includes a coupling part including a conductive material to transfer the test signal from the system circuit to the chamber.

13. The test device as claimed in claim 9, wherein the system circuit includes a site board to:
receive a data signal and a timing signal from the host, and
generate the test signal based on the data signal and timing signal.

14. The test device as claimed in claim 13, wherein the site board includes an algorithm pattern generator to:
receive the data signal from the host, and
generate logic data to control the operation of the device under test based on the data signal.

15. The test device as claimed in claim 14, wherein the site board includes a timing generator to receive:
the timing signal from the host, and
adjust a time interval, in which a logical value of the timing signal is maintained, based on the timing signal and the logic data.

16.-20. (canceled)

21. A non-transitory, computer-readable medium comprising instructions which, when executed, cause a processor to perform a method of:
generating, by a system circuit of a test device, a test signal to test a device under test;
transferring the test signal through an interposer stacked between the system circuit and the test device;
generating, by a pin electronic circuit spatially disposed within a chamber, a control signal to control an operation of the device under test based on the test signal transferred through the interposer; and
testing the device under test based on the control signal at a temperature that is higher or lower than an external temperature of the chamber.

22. The medium as claimed in claim 21, wherein transferring the test signal includes electrically connecting the system circuit and the chamber by the interposer.

23. The medium as claimed in claim 21, further comprising:
receiving a request of a host by the system circuit; and
generating, by the system circuit, the test signal based on the request of the host.

24. The medium as claimed in claim 21, wherein generating the test signal for testing the device under test includes:
receiving a data signal from a host at the system circuit;
generating, by the system circuit, logic data of a logical value to control the operation of the device under test based on the data signal;
receiving a timing signal from the host at the system circuit;
generating, by the system circuit, the test signal having the logical value of the logic data during a specific time interval based on the timing signal and the logic data; and
adjusting the specific time interval by the system circuit.

25. The medium as claimed in claim 24, wherein the pin electronic circuit and the system circuit are implemented with at least one of an ASIC and a FPGA.
